(19) United States
(12) Patent Application Publication
(10) Pub. No.: US 2026/0314073 A1
(43) Pub. Date: Oct. 8, 2026

(54) ELECTRONIC DEVICE

(71) Applicant: Samsung Display Co., Ltd., Yongin-si (KR)

(72) Inventors: Jung Suk BANG, Yongin-si (KR); Taehyun KIM, Yongin-si (KR); Dongil YOO, Yongin-si (KR); Myunghun LIM, Yongin-si (KR)

(73) Assignee: Samsung Display Co., Ltd., Yongin-si (KR)

(21) Appl. No.: 19/540,068

(22) Filed: Feb. 13, 2026

(30) Foreign Application Priority Data
Apr. 2, 2025 (KR) 10-2025-0042530

(51) Int. Cl. H10D 86/60

(52) U.S. Cl. CPC H10D 86/60

(57) ABSTRACT

An electronic device, including: a processor configured to provide image data and a display brightness value; a display panel including a pixel circuit including a plurality of transistors and a plurality of capacitors, a light emitting element connected to the pixel circuit, and a signal line connected to the plurality of transistors; and a panel driver configured to drive the display panel, wherein on a plane, the signal line includes: a first voltage line; a reference scan line below the first voltage line; a first emission signal line below the reference scan line; a first power line below the first emission signal line; a write scan line below the first power line; a second emission signal line below the write scan line; an initialization scan line below the second emission signal line; and a second voltage line below the initialization scan line.

### CROSS-REFERENCE TO RELATED APPLICATIONS

This application is based on and claims priority under 35 U.S.C. § 119 to Korean Patent Application No. 10-2025-0042530 filed on Apr. 02, 2025, in the Korean Intellectual Property Office, the disclosure of which is incorporated by reference herein in its entirety.

### BACKGROUND

The present disclosure relates to an electronic device including a pixel circuit with improved reliability.

A display panel included in an electronic device may include a plurality of pixels, and driving circuits (e.g., a scan driver circuit and a data driver circuit) that may control the plurality of pixels. Each of the plurality of pixels may include a light emitting element and a pixel circuit that may control the light emitting element. The pixel circuit may include a plurality of transistors and at least one capacitor in cooperation with one another. As the resolution of the pixels increases, it may be beneficial to optimize a pixel circuit structure.

### SUMMARY

Provided is an electronic device including a pixel circuit having improved reliability.

Additional aspects will be set forth in part in the description which follows and, in part, will be apparent from the description, or may be learned by practice of the presented embodiments.

In accordance with an aspect of the disclosure, an electronic device includes: a processor configured to provide image data and a display brightness value; a display panel including a pixel circuit including a plurality of transistors and a plurality of capacitors, a light emitting element connected to the pixel circuit, and a signal line connected to the plurality of transistors; and a panel driver configured to receive the image data and the display brightness value, and to drive the display panel based on the image data and the display brightness value, wherein on a plane, the signal line includes: a first voltage line; a reference scan line below the first voltage line; a first emission signal line below the reference scan line; a first power line below the first emission signal line; a write scan line below the first power line; a second emission signal line below the write scan line; an initialization scan line below the second emission signal line; and a second voltage line below the initialization scan line.

The plurality of transistors may include a first transistor, a second transistor, a third transistor, a fourth transistor, a fifth transistor, and a sixth transistor, wherein the first transistor, the second transistor, the third transistor, and the fourth transistor correspond to a first transistor type, and

wherein the fifth transistor and the sixth transistor correspond to a second transistor type different from the first transistor type.

The electronic device may further include: a first node connected to the first transistor and the light emitting element, wherein the first transistor is connected between the first node and the first power line, wherein the fifth transistor is connected between the first power line and a drain of the first transistor, and is connected to the first emission signal line, wherein the sixth transistor is connected between the first node and the light emitting element, and is connected to the second emission signal line, wherein the fifth transistor is configured to receive a first emission signal using the first emission signal line, and wherein the sixth transistor is configured to receive a second emission signal using the second emission signal line.

On the plane, a first semiconductor pattern corresponding to the first transistor may be above a fifth semiconductor pattern corresponding to the fifth transistor and a sixth semiconductor pattern corresponding to the sixth transistor.

On the plane, the fifth semiconductor pattern may be between the first semiconductor pattern and the sixth semiconductor pattern.

The fifth semiconductor pattern and the sixth semiconductor pattern may include poly silicon.

The electronic device may further include: a second node connected to the first transistor and the second transistor, wherein the second transistor is connected between the second node and the write scan line, and is connected to a data line, wherein the third transistor is connected between the second node and the first voltage line, and is connected to the reference scan line, wherein the first voltage line is configured to receive a reference voltage, wherein the second transistor is configured to receive a data signal using the data line, and wherein the third transistor is configured to receive a reference scan signal using the reference scan line.

On the plane, a second semiconductor pattern corresponding to the second transistor may be below a first semiconductor pattern corresponding to the first transistor, and a third semiconductor pattern corresponding to the third transistor may be above the first semiconductor pattern.

The first semiconductor pattern, the second semiconductor pattern, and the third semiconductor pattern may include an oxide semiconductor.

On the plane, a first semiconductor pattern corresponding to the first transistor may be between the reference scan line and the first emission signal line.

In accordance with an aspect of the disclosure, an electronic device includes: a processor configured to provide image data and a display brightness value; a display panel including a pixel circuit, wherein the pixel circuit includes a plurality of transistors, a plurality of capacitors, a light emitting element connected to the pixel circuit, and a signal line connected to the plurality of transistors; and a panel driver configured to receive the image data and the display brightness value, and to drive the display panel based on the image data and the display brightness value, wherein on a plane, the signal line includes: a second voltage line; an initialization scan line below the second voltage line; a second emission signal line below the initialization scan line; a write scan line below the second emission signal line; a reference scan line below the write scan line; a first emission signal line below the reference scan line; a first voltage line below the first emission signal line; and a first power line below the first voltage line.

The plurality of transistors may include a first transistor, a second transistor, a third transistor, a fourth transistor, a fifth transistor, and a sixth transistor, wherein the first transistor, the second transistor, the third transistor, and the fourth transistor correspond to a first transistor type, and

wherein the fifth transistor and the sixth transistor correspond to a second transistor type different from the first transistor type.

The electronic device may further include: a first node connected to the first transistor and the light emitting element, wherein the first transistor is connected between the first node and the first power line, wherein the fifth transistor is connected between the first power line and a drain of the first transistor, and connected is connected to the first emission signal line, wherein the sixth transistor is connected between the first node and the light emitting element and connected to the second emission signal line, wherein the fifth transistor is configured to receive a first emission signal using the first emission signal line, and wherein the sixth transistor is configured to receive a second emission signal using the second emission signal line.

On the plane, a fifth semiconductor pattern corresponding to the fifth transistor may be below a first semiconductor pattern corresponding to the first transistor, and a sixth semiconductor pattern corresponding to the sixth transistor may be above the first semiconductor pattern corresponding to the first transistor.

The fifth semiconductor pattern and the sixth semiconductor pattern may include poly silicon.

The electronic device may further include: a second node connected to the first transistor and the second transistor, wherein the second transistor is connected between the second node and the write scan line, and is connected to a data line, wherein the third transistor is connected between the second node and the first voltage line, and is connected to the reference scan line,

wherein the first voltage line is configured to receive a reference voltage, wherein the second transistor is configured to receive a data signal using the data line, and wherein the third transistor is configured to receive a reference scan signal using the reference scan line.

On the plane, a second semiconductor pattern corresponding to the second transistor may be above a first semiconductor pattern corresponding to the first transistor, and a third semiconductor pattern of the third transistor may be below the first semiconductor pattern corresponding to the first transistor.

The first semiconductor pattern, the second semiconductor pattern, and the third semiconductor pattern may include an oxide semiconductor.

On the plane, a first semiconductor pattern corresponding to the first transistor may be between the write scan line and the reference scan line.

The light emitting element may include a first electrode, a second electrode, and an emissive layer between the first electrode and the second electrode.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1A is a block diagram of an electronic device according to an embodiment;

FIG. 1B illustrates schematic views of electronic devices according to various embodiments;

FIG. 1C is a perspective view of the electronic device according to an embodiment;

FIG. 2 is a view illustrating a cross-section of the electronic device illustrated in FIG. 1C, according to an embodiment;

FIG. 3 is a view illustrating a cross-section of a display panel illustrated in FIG. 2, according to an embodiment;

FIG. 4 is a block diagram of the electronic device according to an embodiment;

FIG. 5 is a circuit diagram of a pixel according to an embodiment;

FIG. 6 is a sectional view of the display panel according to an embodiment;

FIG. 7 is a schematic view illustrating a pixel circuit according to an embodiment;

FIGS. 8A and 8B are schematic views illustrating the pixel circuit illustrated in FIG. 7, according to an embodiment;

FIG. 9 is a schematic view illustrating a pixel circuit according to an embodiment; and

FIGS. 10A and 10B are schematic views illustrating the pixel circuit illustrated in FIG. 9, according to an embodiment.

### DETAILED DESCRIPTION

In the present disclosure, when a first component (e.g., an area, a layer, a part, etc.) is referred to as being “on”, “connected to” or “coupled to” a second component, this may mean that the first component may be directly on, connected to, or coupled to the second component, and also may mean that a third component may be present between the first component and the second component. According to embodiments, a first component that is described as being “connected to” a second component, may also be referred to as being “connected with” the second element.

Identical reference numerals may refer to same or similar components. Additionally, in the drawings, the thicknesses, proportions, and dimensions of components are exaggerated for convenience of depiction. As used herein, the term “and/or” may include all of one or more combinations defined by related components.

Terms such as first, second, and the like may be used to describe various components, but the components are not intended to be limited by the terms. The terms may be used only for distinguishing one component from other components. For example, without departing the scope of the present disclosure, a first component may be referred to as a second component, and similarly, the second component may also be referred to as the first component. The terms of a singular form may include plural forms unless otherwise specified.

In addition, terms such as “below”, “under”, “above”, and “over” are used to describe a relationship between components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Unless otherwise defined, all terms used herein, including technical or scientific terms, may have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Hereinafter, embodiments of the present disclosure are described with reference to the accompanying drawings.

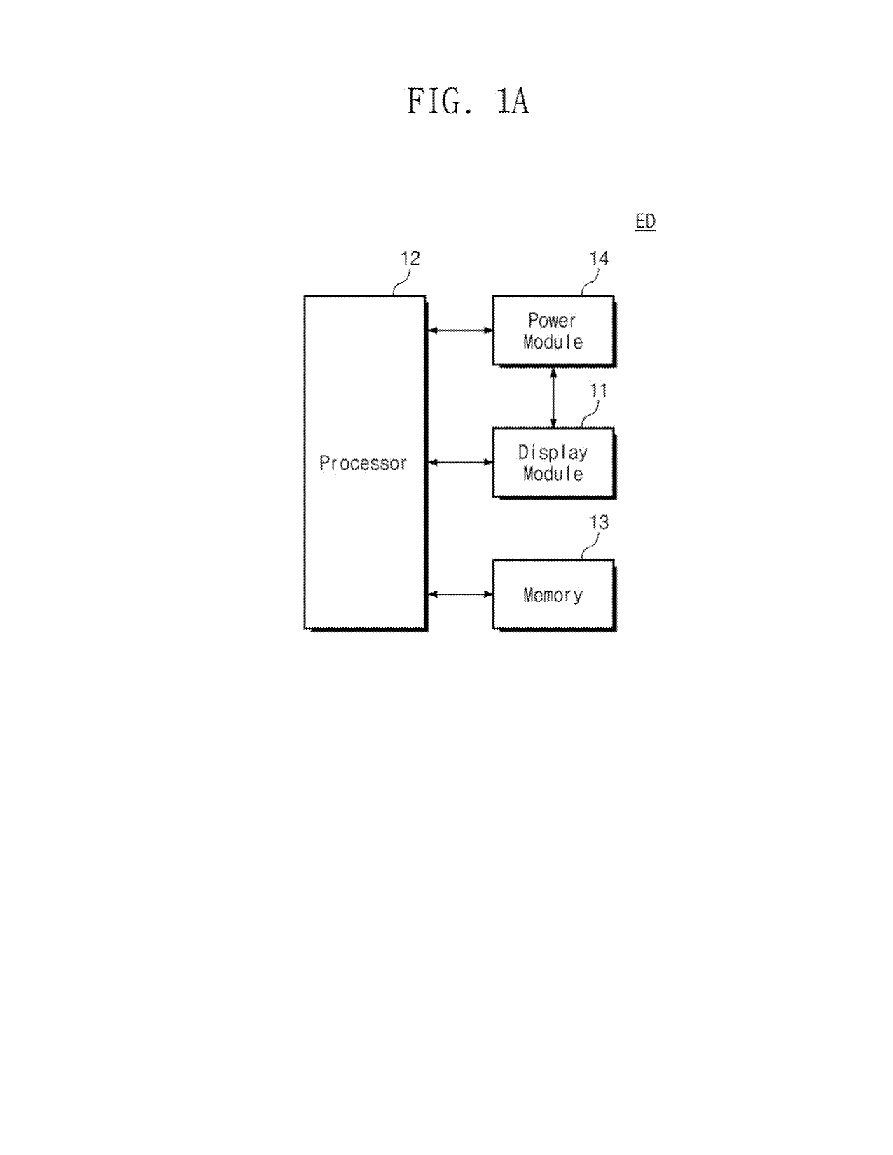

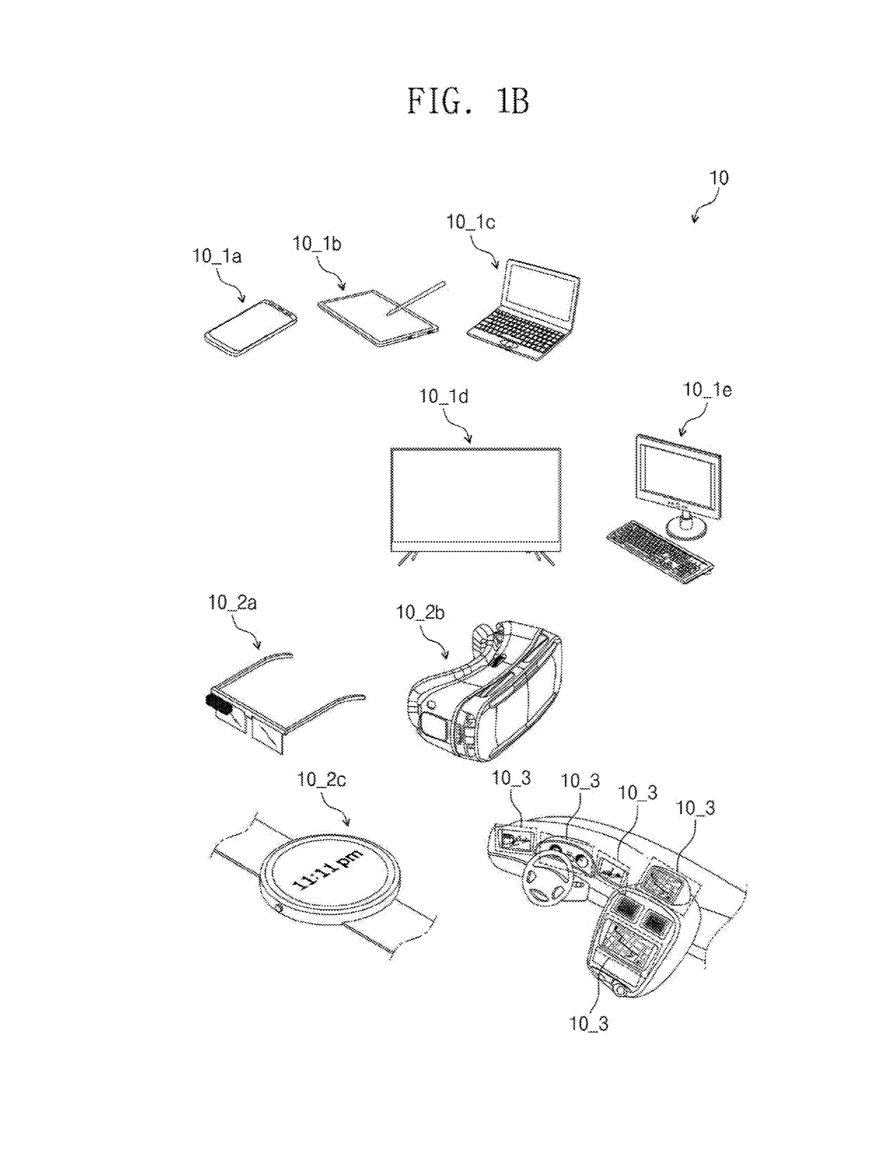

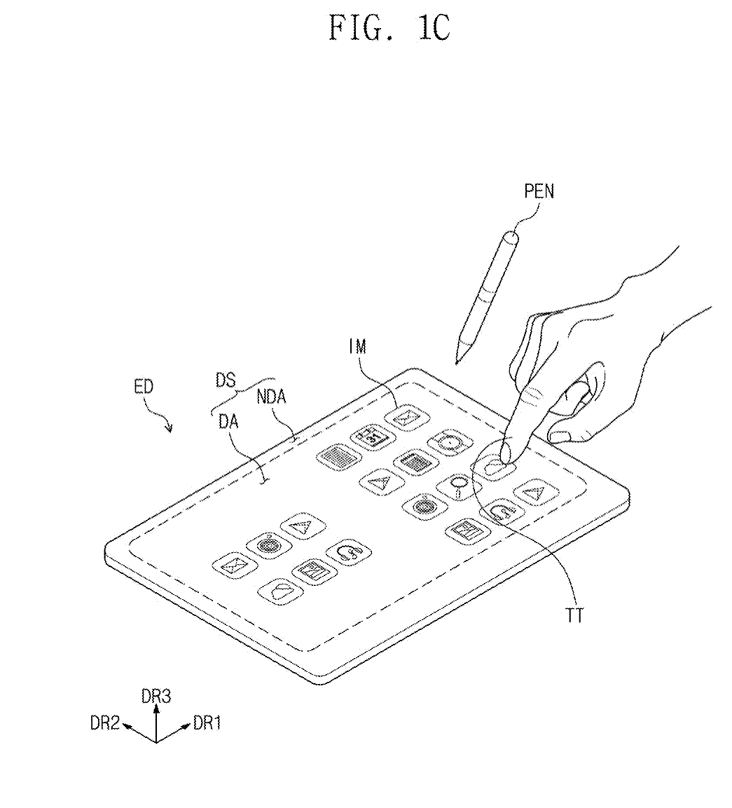

FIG. 1A is a block diagram of an electronic device according to an embodiment. FIG. 1B illustrates schematic views of electronic devices according to various embodiments. FIG. 1C is a perspective view of the electronic device according to an embodiment of the present disclosure.

Referring to FIG. 1A, the electronic device ED according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information used for operation of the processor 12 or the display module 11 may be stored in the memory 15. When the processor 12 executes an application stored in the memory 15, an image data signal and/or an input control signal may be transferred to the display module 11, and the display module 11 may process the provided signal and may output image information using a display screen.

The power module 14 may include a power supply module such as a power adapter or a battery device and a power conversion module that converts power supplied by the power supply module and generates power required for operation of the electronic device ED.

At least one of the components of the electronic device ED described above may be included in the display device according to the above-described embodiments. In addition, some of the separate modules functionally included in one module may be included in the display device, and the others may be provided separately from the display device. For example, the display device may include the display module 11, and the processor 12, the memory 13, and the power module 14 may be provided in the form of other devices in the electronic device ED rather than the display device.

Referring to FIG. 1B, various electronic devices to which display devices according to embodiments are applied may include electronic devices for displaying images, such as a smart phone 10_1a, a tablet PC 10_1b, a laptop computer 10_1c, a TV 10_1d, and a desk monitor 10_1e, and also may include wearable electronic devices including a display module, such as smart glasses 10_2a, a head mounted display 10_2b, and a smart watch 10_2c, and vehicle electronic devices 10_3 including a display module, such as center information displays disposed on an instrument panel, a center fascia, and a dashboard of a vehicle and a room mirror display.

A display device according to an embodiment may be applied to various electronic devices. An electronic device according to an embodiment may include the display device described above and may further include modules or devices having other additional functions, in addition to the display device.

Referring to FIG. 1C, the electronic device ED according to an embodiment may have long sides (e.g., sides having a first length) extending parallel to each other in a first direction DR1, and short sides (e.g., side having a second length shorter than the first length) extending parallel to each other in a second direction DR2 crossing the first direction DR1. The corners of the electronic device ED that connect the long sides and the short sides may have a curved shape. The corners of the electronic device ED that have a curved shape may be referred to as rounded corners. The shape of the electronic device ED may be referred to as a rounded rectangular shape.

Hereinafter, a direction substantially perpendicular to a plane defined by the first direction DR1 and the second direction DR2 may be referred to as a third direction DR3. In addition, when an element is described as being “viewed from above the plane”, as used herein, this means that the element is viewed in the third direction DR3.

The front surface of the electronic device ED may be referred to as a display surface DS, and may have, or may correspond to, a plane defined by the first direction DR1 and the second direction DR2. Images IM generated by the electronic device ED may be provided to a user through the display surface DS.

The display surface DS may include a display area DA and a non-display area NDA around the display area DA. The display area DA may display an image, and the non-display area NDA may not display an image. The non-display area NDA may be around or surround the display area DA and may define the border of the electronic device ED that is printed in a certain color.

The display area DA may have a rounded rectangular shape depending on the shape of the electronic device ED. For example, the display area DA may include sides of a rectangle that extend in the first direction DR1 and the second direction DR2 and rounded corners that connect the sides. Among the four sides, sides extending in the first direction DR1 may be referred to as long sides, and sides extending in the second direction DR2 may be referred to as short sides.

The electronic device ED may sense one or more inputs applied from outside the electronic device ED. For example, the electronic device ED may sense a first input by a touch pen PEN and a second input by a touch TT. The touch pen PEN may be referred to as an input device.

The touch pen PEN may be an active pen that outputs a signal. The second input by the touch TT may include various types of external inputs such as a body part of a user, light, heat, or pressure.

The electronic device ED and the touch pen PEN may bidirectionally communicate with each other. The electronic device ED may provide an uplink signal to the touch pen PEN. For example, the uplink signal may include information such as panel information and protocol version, but is not particularly limited thereto.

The touch pen PEN may provide a downlink signal to the electronic device ED. The downlink signal may include a synchronization signal or status information of the touch pen PEN. For example, the downlink signal may include coordinate information of the touch pen PEN, battery information of the touch pen PEN, tilt information of the touch pen PEN, and/or various pieces of information stored in the touch pen PEN, but is not particularly limited thereto.

The electronic device ED may be used in large electronic devices such as a television, a monitor, and a billboard. In addition, the electronic device ED may be used in small and medium-sized electronic devices such as a personal computer, a notebook computer, a personal digital assistant, a car navigation device, a game machine, a smart phone, a tablet computer, and a camera. However, these are merely examples, and the electronic device ED may be used in other electronic devices without departing from the spirit and scope of the present disclosure.

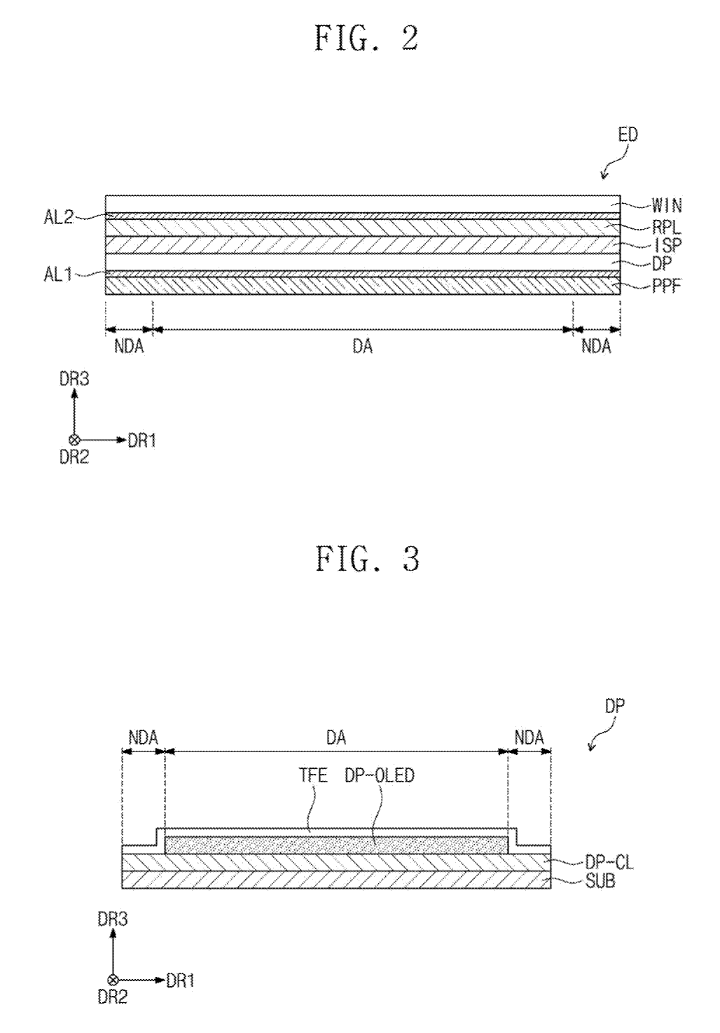

FIG. 2 is a view illustrating a cross-section of the electronic device illustrated in FIG. 1C. According to embodiments, FIG. 2 illustrates an example of a cross-section of the electronic device ED viewed in the second direction DR2 is illustrated.

Referring to FIG. 2, the electronic device ED may include a display panel DP, an input sensing part ISP, an anti-reflective layer RPL, a window WIN, a panel protection film PPF, a first adhesive layer AL1, and a second adhesive layer AL2.

The display panel DP according to an embodiment of the present disclosure may be an emissive display panel. For example, the display panel DP may be an organic light emitting display panel or an inorganic light emitting display panel. An emissive layer of the organic light emitting display panel may include an organic luminescent material. An emissive layer of the inorganic light emitting display panel may include a quantum dot and a quantum rod. Hereinafter, an example is described in which the display panel DP is an organic light emitting display panel, but embodiments are not limited thereto.

The input sensing part ISP may be disposed on the display panel DP. The input sensing part ISP may include a plurality of sensing parts (e.g., sensors such as capacitive sensors) for sensing an external input in a capacitive type. The input sensing part ISP may be directly manufactured on the display panel DP when the electronic device ED is manufactured. However, embodiments are not limited thereto. For example, in some embodiments, the input sensing part ISP may be manufactured as a panel separate from the display panel DP, and may be attached to the display panel DP by an adhesive layer.

The anti-reflective layer RPL may be disposed on the input sensing part ISP. The anti-reflective layer RPL may be directly manufactured on the input sensing part ISP when the electronic device ED is manufactured. However, embodiments are not limited thereto. For example, in some embodiments, the anti-reflective layer RPL may be manufactured as a separate panel and may be attached to the input sensing part ISP by an adhesive layer.

The anti-reflective layer RPL may be referred to as a film for preventing reflection of external light. The anti-reflective layer RPL may decrease the reflectance of external light incident toward the display panel DP from above the electronic device ED. Due to the anti-reflective layer RPL, the external light may not be visible to the user.

When the external light traveling toward the display panel DP is reflected by the display panel DP and then provided back to the user, the user may visually recognize the external light as in a mirror. To prevent such a phenomenon, for example, the anti-reflective layer RPL may include a plurality of color filters that display the same colors as pixels of the display panel DP.

The color filters may filter the external light in the same colors as the pixels. In this case, the external light may not be visible to the user. However, embodiments are not limited thereto. For example, in some embodiments, the anti-reflective layer RPL may include a phase retarder and/or a polarizer to decrease the reflectance of the external light.

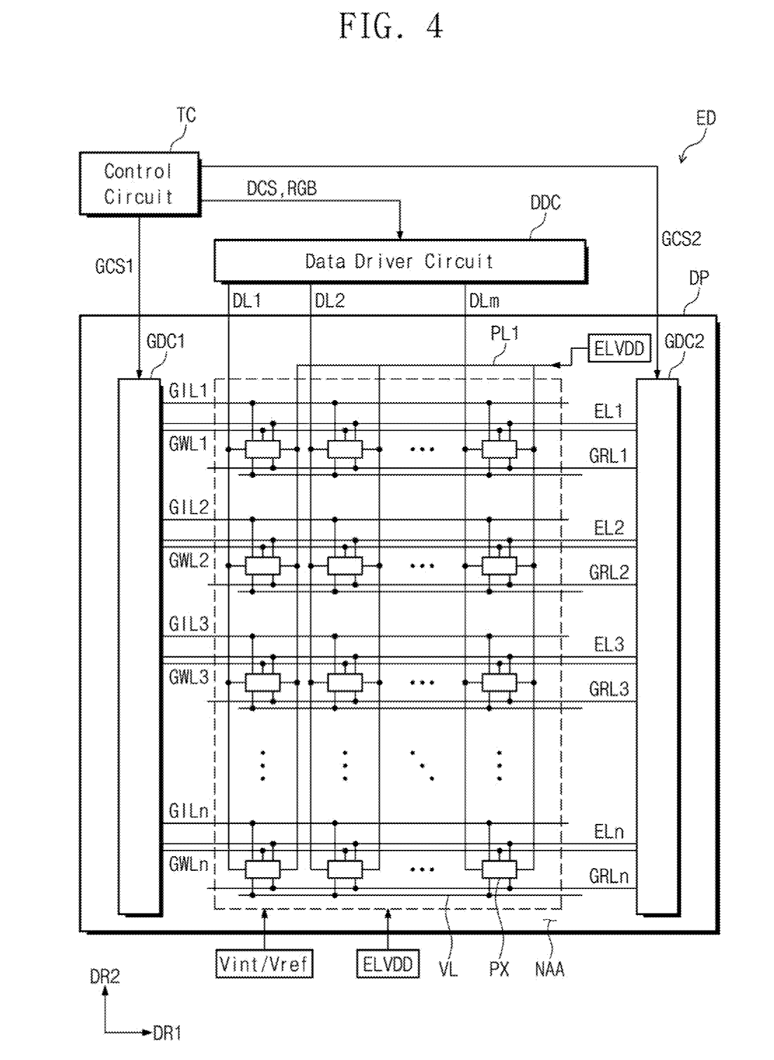

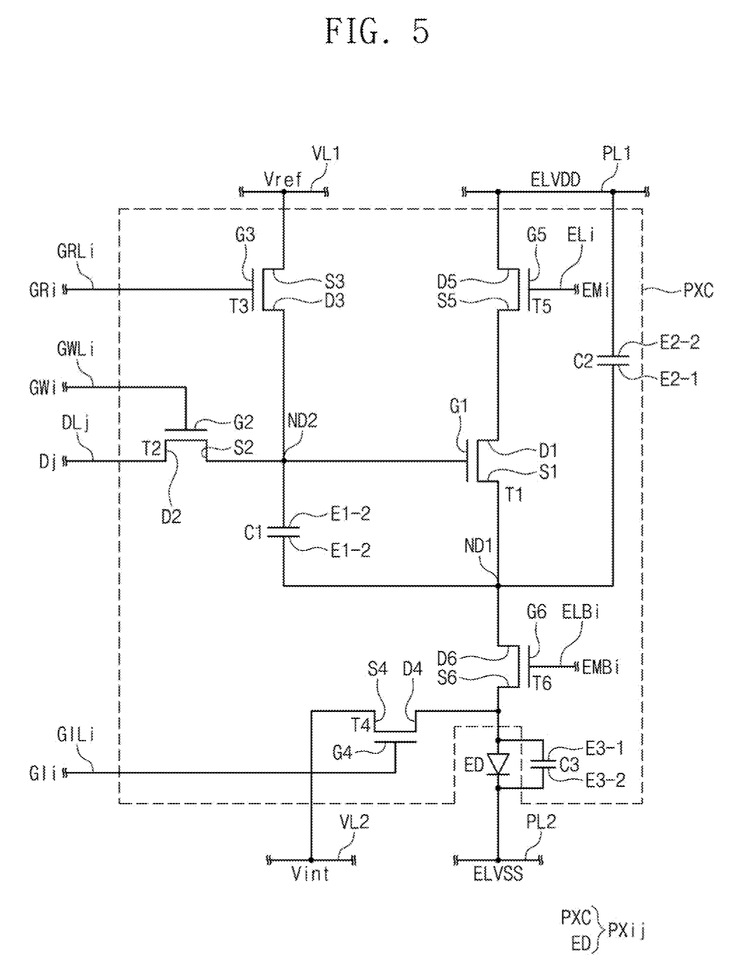

The electronic device ED according to an embodiment may further include a camera module. The camera module may be disposed under the display panel DP overlapping the display area DA. A pixel circuit PC (e.g., as shown in FIG. 5) included in a pixel PX (e.g., as shown in FIG. 4) that overlaps the camera module and a pixel circuit PC (e.g., as shown in FIG. 5) included in a pixel PX (e.g., as shown in FIG. 4) that does not overlap the camera module may have a stack structure of conductive layers as described below, and are not limited to any one example described herein.

The window WIN may be disposed on the anti-reflective layer RPL. The window WIN may protect the display panel DP, the input sensing part ISP, and the anti-reflective layer RPL from external scratches and impacts.

The panel protection film PPF may be disposed under the display panel DP. The panel protection film PPF may protect the bottom of the display panel DP. The panel protection film PPF may include a flexible plastic material such as polyethyleneterephthalate (PET).

The first adhesive layer AL1 may be disposed between the display panel DP and the panel protection film PPF, and the display panel DP and the panel protection film PPF may be bonded to each other by the first adhesive layer AL1. The second adhesive layer AL2 may be disposed between the window WIN and the anti-reflective layer RPL, and the window WIN and the anti-reflective layer RPL may be bonded to each other by the second adhesive layer AL2.

FIG. 3 is a view illustrating a cross-section of the display panel illustrated in FIG. 2.

According to embodiments, FIG. 3 illustrates an example of a cross-section of the display panel DP viewed in the second direction DR2.

Referring to FIG. 3, the display panel DP may include a base layer SUB, a circuit element layer DP-CL disposed on the base layer SUB, a display element layer DP-OLED disposed on the circuit element layer DP-CL, and a thin film encapsulation layer TFE disposed on the display element layer DP-OLED.

The base layer SUB may include a display area DA and a non-display area NDA around the display area DA. The base layer SUB may include glass or may include a flexible plastic material such as polyimide (PI). The display element layer DP-OLED may be disposed on the display area DA.

A plurality of pixels may be disposed in the circuit element layer DP-CL and the display element layer DP-OLED. Each of the pixels may include a transistor disposed in the circuit element layer DP-CL and a light emitting element disposed in the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and external foreign matter.

FIG. 4 is a block diagram of the electronic device according to an embodiment of the present disclosure.

Referring to FIG. 4, the electronic device ED may include the display panel DP, a first gate driver circuit GDC1, a second gate driver circuit GDC2, a data driver circuit DDC, and a control circuit TC.

The control circuit TC controls operation of the first gate driver circuit GDC1, the second gate driver circuit GDC2, and the data driver circuit DDC. The control circuit TC generates image data RGB by converting the data format of input image signals according to the specification of an interface with the data driver circuit DDC. The control circuit TC outputs the image data RGB and various types of control signals DCS, GCS1, and GCS2.

The first gate driver circuit GDC1 receives the first gate control signal GCS1 from the control circuit TC, and the second gate driver circuit GDC2 receives the second gate control signal GCS2 from the control circuit TC. The first gate control signal GCS1 may include a start signal for starting operation of the first gate driver circuit GDC1 and a clock signal for determining output timing of signals, and the second gate control signal GCS2 may include a start signal for starting operation of the second gate driver circuit GDC2 and a clock signal for determining output timing of signals. The first gate driver circuit GDC1 and the second gate driver circuit GDC2 output a plurality of scan signals to a plurality of scan lines GWL1 to GWLn, GRL1 to GRLn, and GIL1 to GILn, examples of which are described below. Among the plurality of scan lines GWL1 to GWLn, GRL1 to GRLn, and GIL1 to GILn, the first group of scan lines GWL1 to GWLn may be referred to as write scan lines. Among the plurality of scan lines GWL1 to GWLn, GRL1 to GRLn, and GIL1 to GILn, the second group of scan lines GRL1 to GRLn may be referred to as reference scan lines. Among the plurality of scan lines GWL1 to GWLn, GRL1 to GRLn, and GIL1 to GILn, the third group of scan lines GIL1 to GILn may be referred to as initialization scan lines.

In addition, at least one of the first gate driver circuit GDC1 and the second gate driver circuit GDC2 generates a plurality of emission control signals and outputs the plurality of emission control signals to a plurality of emission signal lines EL1 to ELn.

The data driver circuit DDC receives the data control signal DCS and the image data RGB from the control circuit TC. The data driver circuit DDC converts the image data RGB into data signals and outputs the data signals to a plurality of data lines DL1 to DLm, examples of which are described below. The data signals are analog voltages corresponding to grayscale values of the image data RGB.

The display panel DdP includes the plurality of scan lines GWL1 to GWLn, GRL1 to GRLn, and GIL1 to GILn, the plurality of emission signal lines EL1 to ELn, the plurality of data lines DL1 to DLm, and a plurality of pixels PX. The plurality of scan lines GWL1 to GWLn, GRL1 to GRLn, and GIL1 to GILn extend in the first direction DR1 and are arranged in the second direction DR2 perpendicular to the first direction DR1. Each of the plurality of emission signal lines EL1 to Eln may be arranged parallel to a corresponding scan line among the plurality of scan lines GWL1 to GWLn, GRL1 to GRLn, and GIL1 to GILn. The plurality of data lines DL1 to DLm cross the plurality of scan lines GWL1 to GWLn, GRL1 to GRLn, and GIL1 to GILn in order to be insulated from the plurality of scan lines GWL1 to GWLn, GRL1 to GRLn, and GIL1 to GILn.

Each of the plurality of pixels PX is connected to a corresponding scan line among the plurality of scan lines GWL1 to GWLn, GRL1 to GRLn, and GIL1 to GILn, a corresponding emission signal line among the plurality of emission signal lines EL1 to ELn, and a corresponding data line among the plurality of data lines DL1 to DLm.

The display panel DP receives a first power supply voltage ELVDD and a second power supply voltage ELVSS. The first power supply voltage ELVDD may be provided to the plurality of pixels PX through a first power line PL1. The second power supply voltage ELVSS may be provided to the plurality of pixels PX through a second power line PL2 (e.g., as shown in FIG. 5) formed in the display panel DP.

The display panel DP additionally receives an initialization voltage Vint and a reference voltage Vref. The initialization voltage Vint and the reference voltage Vref may be provided to the plurality of pixels PX through a voltage line VL.

FIG. 5 is a circuit diagram of a pixel according to an embodiment of the present disclosure. According to embodiments, FIG. 5 is an example of a circuit diagram of the pixel PXij among the pixels PX illustrated in FIG. 4.

In FIG. 5, the pixel PXij connected to the i-th write scan line GWLi among the plurality of write scan lines GWL1 to GWLn (e.g., as shown in FIG. 4) to receive the i-th write scan signal GWi and connected to the j-th data line DLj among the plurality of data lines DL1 to DLm (e.g., as shown in FIG. 4) to receive the j-th data signal Dj is illustrated as an example. The pixel PXij is connected to the i-th reference scan line GRLi among the reference scan lines GRL1 to GRLn (e.g., as shown in FIG. 4) to receive the i-th reference scan signal GRi and is connected to the i-th initialization scan line GILi among the initialization scan lines GIL1 to GILn (e.g., as shown in FIG. 4) to receive the i-th initialization scan signal GIi.

The pixel PXij may include a pixel circuit (e.g., a pixel driving circuit) PXC and a light emitting element OLED electrically connected to the pixel circuit PXC. In embodiments, the pixel circuit PXC may include six transistors (e.g., a first transistor T1, a second transistor T2, a third transistor T3, a fourth transistor T4, a fifth transistor T5, and a sixth transistor T6) and two capacitors (e.g., a first capacitor C1 and a second capacitor C2). In embodiments, the first to fourth transistors T1 to T4 may have a first transistor type (e.g., may be N-type transistors). The fifth transistor T5 and the sixth transistor T6 may have a second transistor type (e.g., may be P-type transistors). In an embodiment of the present disclosure, at least one of the first to fourth transistors T1 to T4 may be omitted from the pixel PXij, or at least one additional transistor may be further included in the pixel PXij.

According to an embodiment, each of the first transistor T1 and the second transistor T2 may include two gates (e.g., an upper gate and a lower gate). In some embodiments, at least one of the first transistor T1 and the second transistor T2 may include only one gate.

In embodiments, the first transistor T1 may be referred to as a driving transistor, and the second transistor T2 may be referred to as a switching transistor. A node to which the first transistor T1 and the light emitting element OLED are connected may be referred to as a first node ND1, and a node to which the first transistor T1 and the second transistor T2 are connected may be referred to as a second node ND2.

The light emitting element OLED includes a first electrode electrically connected to the first node ND1, a second electrode connected to the second power line PL2 that receives the second power supply voltage ELVSS, and an emissive layer disposed between the first electrode and the second electrode. An example of the light emitting element OLED is described in greater detail below.

The first transistor T1 is electrically connected between the first power line PL1 that receives the first power supply voltage ELVDD and the first node ND1. The first transistor T1 may include a source S1 connected to the first node ND1, a drain D1, a semiconductor area, and a gate G1 electrically connected to the first node ND1. According to an embodiment, the first transistor T1 may further include a lower gate connected to the first node ND1. In the present disclosure, the phrase “a source, a drain, and a semiconductor area” included in a transistor may be obtained by dividing “one semiconductor pattern” based on areas.

The second transistor T2 is electrically connected between the j-th data line DLj and the second node ND2. The second transistor T2 may include a source S2 connected to the second node ND2, a drain D2 connected to the j-th data line DLj, a semiconductor area, and a gate G2 connected to the i-th write scan line GWLi. According to an embodiment, the second transistor T2 may further include a lower gate electrically connected to the gate G2.

The third transistor T3 is electrically connected between the second node ND2 and a first voltage line VL1 that receives the reference voltage Vref. The third transistor T3 may include a drain D3 connected to the second node ND2, a source S3 connected to the first voltage line VL1, a semiconductor area, and a gate G3 connected to the i-th reference scan line GRLi. According to an embodiment, the third transistor T3 may further include a lower gate electrically connected to the gate G3.

The fourth transistor T4 is electrically connected between a second voltage line VL2 that receives the initialization voltage Vint and the light emitting element OLED. The fourth transistor T4 may include a drain D4 (which may be referred to as the fourth drain) connected to the first node ND1, a source S4 connected to the second voltage line VL2, a semiconductor area, and a gate G4 connected to the i-th initialization scan line GILi. According to an embodiment, the fourth transistor T4 may further include a lower gate electrically connected to the gate G4.

The fifth transistor T5 is electrically connected between the first power line PL1 and the drain D1 of the first transistor T1. In embodiments, the fifth transistor T5 may include a drain D5 connected to the first power line PL1, a source S5 connected to the drain D1 of the first transistor T1, a semiconductor area, and a gate G5 that is connected to the i-th first emission signal line ELi and that receives the i-th first emission signal EMi. The fifth transistor T5 may further include a lower gate electrically connected to the gate G5.

The sixth transistor T6 is electrically connected between the first node ND1 and the light emitting element OLED. In embodiments, the sixth transistor T6 may include a drain D6 connected to the first node ND1, a source S6 connected to the first electrode of the light emitting element OLED, a semiconductor area, and a gate G6 that is connected to the i-th second emission signal line ELBi and that receives the i-th second emission signal EMBi. The sixth transistor T6 may further include a lower gate electrically connected to the gate G6.

The first capacitor C1 is electrically connected between the first node ND1 and the second node ND2. The first capacitor C1 includes a first-first capacitor pattern E1-1 connected to the first node ND1 and a first-second capacitor pattern E1-2 connected to the second node ND2.

The second capacitor C2 is electrically connected between the first power line PL1 and the first node ND1. The second capacitor C2 may include a second-first capacitor pattern E2-1 connected to the first node ND1 and a second-second capacitor pattern E2-2 connected to the first power line PL1.

A third capacitor C3 is electrically connected between the first electrode and the second electrode of the light emitting element OLED. The third capacitor C3 includes a first capacitor pattern E3-1 connected to the first electrode of the light emitting element OLED and a second capacitor pattern E3-2 connected to the second electrode of the light emitting element OLED.

According to an embodiment, one of the first to third capacitors C1, C2, and C3 may be omitted.

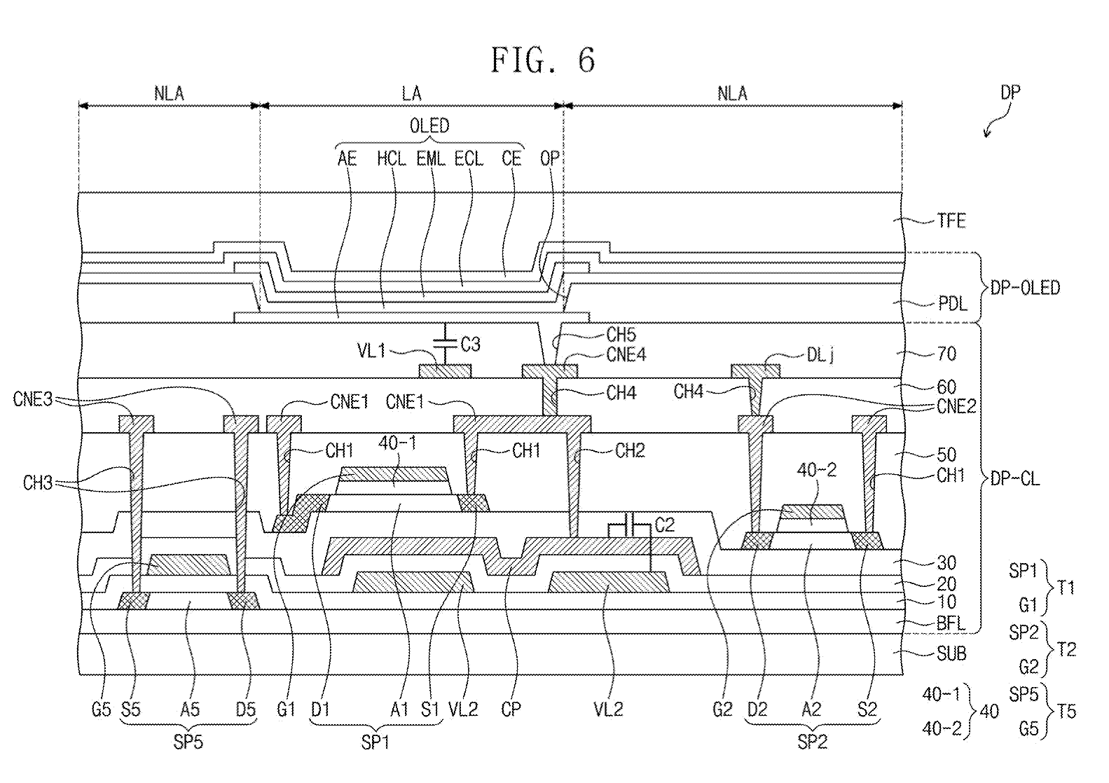

FIG. 6 is a sectional view of the display panel according to an embodiment of the present disclosure.

Referring to FIG. 6, the display panel DP may include the base layer SUB, and the circuit element layer DP-CL, the display element layer DP-OLED, and the thin film encapsulation layer TFE that are disposed on the base layer SUB. The display panel DP according to an embodiment may further include functional layers such as an anti-reflective layer or a refractive index control layer that is disposed on the thin film encapsulation layer TFE.

The base layer SUB may include a synthetic resin layer. The synthetic resin layer may include a thermosetting resin. For example, the synthetic resin layer may be, or may include, a polyimide resin layer, but embodiments are not limited thereto. For example, the synthetic resin layer may include at least one of an acrylic resin, a methacrylic resin, a polyisoprene resin, a vinyl resin, an epoxy resin, a urethane-based resin, a celluosic resin, a siloxane-based resin, a polyamide resin, and a perylene-based resin. In addition, the base layer may include a glass base layer, a metal base layer, or an organic/inorganic composite base layer. The base layer may include a first polyimide layer, a second polyimide layer, and an inorganic layer disposed therebetween.

A buffer layer BFL including at least one inorganic layer is disposed on the upper surface of the base layer SUB. The buffer layer BFL may include at least one of aluminum oxide, titanium oxide, silicon oxide, silicon nitride, silicon oxy nitride, zirconium oxide, and hafnium oxide. The inorganic layer may be formed of multiple layers. The buffer layer BFL may prevent the inflow of foreign matter from the outside. The buffer layer BFL improves the coupling force between the base layer SUB and a semiconductor pattern and/or a conductive pattern disposed on the buffer layer BFL.

A silicon semiconductor layer is disposed on the buffer layer BFL. The silicon semiconductor layer may include a plurality of semiconductor patterns. In embodiments, a semiconductor pattern may be a silicon semiconductor pattern SP5. The silicon semiconductor pattern SP5 (which may be referred to as a fifth semiconductor pattern) may be a semiconductor pattern corresponding to the fifth transistor T5.

The silicon semiconductor pattern SP5 may include a silicon semiconductor. For example, the silicon semiconductor may include amorphous silicon or polycrystalline silicon. For example, the silicon semiconductor pattern SP5 may include poly silicon crystallized at low temperature (which may be referred to as the crystalline poly silicon).

The silicon semiconductor pattern SP5 may have different electrical properties based on on whether doping is performed or not. The fifth source S5, the fifth drain D5, and the fifth channel area described with reference to FIG. 5 may be formed from the silicon semiconductor pattern SP5. The fifth source S5, the fifth drain D5, and the channel area may correspond to the fifth source S5, the fifth drain D5, and the fifth channel area of FIG. 5. The fifth source S5 and the fifth drain D5 may extend from the fifth channel area in opposite directions.

In embodiments, the fifth source S5 may be referred to as a fifth input area, and the fifth drain D5 may be referred to as a fifth output area. Although an example is described in which the fifth transistor T5 is a P-type transistor, embodiments are not limited thereto. For example, in some embodiments, the fifth transistor T5 may be an N-type transistor, and the fifth source S5 and the fifth drain D5 may be referred to in the opposite manner. For example, when the fifth transistor T5 is an N-type transistor, the fifth drain D5 may be referred to as the fifth input area, and the fifth source S5 may be referred to as the fifth output area.

The semiconductor pattern corresponding to the sixth transistor T6 described with reference to FIG. 5 may also be disposed on the same layer as the silicon semiconductor pattern SP5. The semiconductor pattern corresponding to the sixth transistor T6 may be formed through the same process as the silicon semiconductor pattern SP5 and may include the same semiconductor. The silicon semiconductor pattern SP5 is disposed on a different insulating layer than the first semiconductor pattern SP1 and the second semiconductor pattern SP2, examples of which are described below. The expression “disposed on a different insulating layer” used herein means that they make contact with the upper surfaces of different insulating layers among insulating layers disposed on the base layer SUB.

In FIGS. 5 and 6, the fifth transistor T5 and the sixth transistor T6 may include a crystalline poly silicon semiconductor pattern so that the response speed of the fifth transistor T5 and the sixth transistor T6 may be increased. This is because the crystalline poly silicon semiconductor pattern has faster mobility than other semiconductors.

A first insulating layer 10 is disposed on the buffer layer BFL to cover the fifth semiconductor pattern SP5. In embodiments, the first insulating layer 10 may be an inorganic layer and/or an organic layer and may have a single-layer structure or a multi-layer structure. In embodiments, the first insulating layer 10 may include silicon oxide, silicon nitride, or silicon oxy nitride.

A conductive layer (which may be referred to as the first conductive layer) is disposed on the first insulating layer 10. The first conductive layer may include a plurality of conductive patterns (which may be referred to as the first conductive patterns). In FIG. 6, the fifth gate G5 and the second voltage line VL2 are illustrated as an example of the first conductive patterns. The fifth gate G5 may correspond to the fifth gate G5 of FIG. 5 and may have substantially the same area as the fifth channel area.

FIG. 6 illustrates an example in which the second voltage line VL2 is divided into two parts. However, embodiments are not limited thereto, and in some embodiments, the second voltage line VL2 may have a one-body shape (e.g., may not be divided in two parts). In addition, the conductive pattern receiving the first power supply voltage ELVDD may be disposed on the first insulating layer 10, and the second voltage line VL2 may not necessarily be disposed on the first insulating layer 10.

A second insulating layer 20 is disposed on the first insulating layer 10 to cover the first conductive layer. In embodiments, the second insulating layer 20 may be an inorganic layer and/or an organic layer and may have a single-layer structure or a multi-layer structure. In embodiments, the second insulating layer 20 may include silicon oxide, silicon nitride, or silicon oxy nitride.

A conductive layer (which may be referred to as the second conductive layer) is disposed on the second insulating layer 20. The second conductive layer may include a plurality of conductive patterns (which may be referred to as the second conductive patterns). In FIG. 6, one conductive pattern CP is illustrated as an example of the second conductive patterns, but embodiments are not limited thereto. The conductive pattern CP may correspond to the second-second capacitor pattern E2-2 of the second capacitor C2 described with reference to FIG. 5. The conductive pattern CP, together with the second voltage line VL2 disposed below the conductive pattern CP, may be included in the second capacitor C2 described with reference to FIG. 5.

A third insulating layer 30 is disposed on the second insulating layer 20 to cover the second conductive layer. In embodiments, the third insulating layer 30 may be an inorganic layer and/or an organic layer and may have a single-layer structure or a multi-layer structure. In embodiments, the third insulating layer 30 may include silicon oxide, silicon nitride, or silicon oxy nitride.

A metal oxide semiconductor layer is disposed on the third insulating layer 30. The metal oxide semiconductor layer may include a plurality of semiconductor patterns. In embodiments, the first semiconductor pattern SP1 and the second semiconductor pattern SP2 that include different metal oxide semiconductors may be disposed on the third insulating layer 30. The first semiconductor pattern SP1 may be a semiconductor pattern corresponding to the first transistor T1 of FIG. 5, and the second semiconductor pattern SP2 may be a semiconductor pattern corresponding to the second transistor T2 of FIG. 5.

In some embodiments, the semiconductor patterns corresponding to the third transistor T3 and the fourth transistor T4 described with reference to FIG. 5 may also be formed through the same process as the second semiconductor pattern SP2 and may include the same semiconductor.

The first semiconductor pattern SP1 may include a crystalline oxide semiconductor, and the second semiconductor pattern SP2 may include an amorphous oxide semiconductor. The first semiconductor pattern SP1 may include a crystalline indium gallium oxide (IGO) semiconductor, and the second semiconductor pattern SP2 may include one of an amorphous indium gallium zinc oxide (IGZO) semiconductor and an amorphous indium tin gallium zinc oxide (ITGZO) semiconductor. A transistor including an oxide semiconductor has a lower leakage current than a transistor including a silicon semiconductor.

Each of the first semiconductor pattern SP1 and the second semiconductor pattern SP2 may include a plurality of areas distinguished from one another depending on whether metal oxide is reduced or not. An area in which metal oxide is reduced (which may be referred to as the reduced area) has a higher conductivity than an area in which metal oxide is not reduced (which may be referred to as the non-reduced area). The reduced area substantially serves as a source or drain of a transistor or a signal transmission area. The non-reduced area substantially corresponds to a channel area (e.g., a semiconductor area or a non-reduced area) of the transistor. For example, a portion of a semiconductor pattern may be a channel area of a transistor, another portion may be a source or drain of the transistor, and a remaining portion may be a signal transmission area.

The first source S1, the first drain D1, and the channel area described with reference to FIG. 5 may be formed from the first semiconductor pattern SP1. The first source S1, the first drain D1, and the channel area may correspond to the first source S1, the first drain D1, and the first channel area of FIG. 5. The first source S1 and the first drain D1 may extend from the first channel area in opposite directions. In embodiments, the first drain D1 may be referred to as a first input area, and the first source S1 may be referred to as a first output area. Although an example is described in which the first transistor T1 is an N-type transistor, embodiments are not limited thereto. For example, in some embodiments, the first transistor T1 may be a P-type transistor, and the first source S1 and the first drain D1 may be referred to in the opposite manner. For example, when the first transistor T1 is a P-type transistor, the first drain D1 may be referred to as the first output area, and the first source S1 may be referred to as the first input area.

The second source S2, the second drain D2, and the channel area described with reference to FIG. 5 may be formed from the second semiconductor pattern SP2. The second source S2, the second drain D2, and the channel area may correspond to the second source S2, the second drain D2, and the second channel area of FIG. 5. The second source S2 and the second drain D2 may extend from the second channel area in opposite directions. In embodiments, the second drain D2 may be referred to as a second input area, and the second source S2 may be referred to as a second output area. Although an example is described in which the second transistor T2 is an N-type transistor, embodiments are not limited thereto. For example, in some embodiments, the second transistor T2 may be a P-type transistor, and the second source S2 and the second drain D2 may be referred to in the opposite manner. For example, when the second transistor T2 is a P-type transistor, the second drain D2 may be referred to as the second output area, and the second source S2 may be referred to as the second input area.

A fourth insulating layer 40 is disposed on the first semiconductor pattern SP1 and the second semiconductor pattern SP2. In embodiments, the fourth insulating layer 40 may include silicon oxide, silicon nitride, or silicon oxy nitride.

In embodiments, the fourth insulating layer 40 is not formed on the entire surface of the third insulating layer 30, but overlaps only the channel areas of the transistors. The fourth insulating layer 40 may include a plurality of insulating patterns. In FIG. 6, a first insulating pattern 40-1 and a second insulating pattern 40-2 are illustrated as an example, but embodiments are not limited thereto. In an embodiment of the present disclosure, the fourth insulating layer 40 may overlap the entire surface of the third insulating layer 30 without being subjected to patterning.

A conductive layer (which may be referred to as a third conductive layer) is disposed on the fourth insulating layer 40. The first gate G1 is disposed on the first insulating pattern 40-1, and the second gate G2 is disposed on the second insulating pattern 40-2. The first gate G1 of FIG. 6 corresponds to the first gate G1 of FIG. 5, and the second gate G2 of FIG. 6 corresponds to the second gate G2 of FIG. 5.

Because the insulating layer is etched using the first gate G1 and the second gate G2 as a mask after the first gate G1 and the second gate G2 are formed, a shape of the first insulating pattern 40-1 may be substantially the same as, or similar to, a shape of the first gate G1. Similarly, a shape of the second insulating pattern 40-2 may be substantially the same as, or similar to, a shape of the second gate G2. The edge of the gate and the edge of the insulating pattern that overlap each other may be aligned with each other.

A fifth insulating layer 50 is disposed on the third insulating layer 30. The fifth insulating layer 50 may cover the first gate G1 and the second gate G2. In embodiments, the fifth insulating layer 50 may be an inorganic layer and/or an organic layer and may have a single-layer structure or a multi-layer structure. In embodiments, the fifth insulating layer 50 may include silicon oxide, silicon nitride, or silicon oxy nitride.

A conductive layer (which may be referred to as the fourth conductive layer) is disposed on the fifth insulating layer 50. The fourth conductive layer may include a plurality of conductive patterns (which may be referred to as the fourth conductive patterns). In FIG. 6, three types of connecting electrodes CNE1, CNE2, and CNE3 are illustrated as an example of the fourth conductive patterns, but embodiments are not limited thereto.

The first connecting electrode CNE1 connected to at least one of the first source S1 and the first drain D1 may be disposed on the fifth insulating layer 50. In the example shown in FIG. 6, two first connecting electrodes CNE1 are connected to the first source S1 and the first drain D1, respectively, but embodiments are not limited thereto. The first connecting electrodes CNE1 are connected to corresponding areas of the first source S1 and the first drain D1 through contact holes CH1 penetrating the fifth insulating layer 50.

One first connecting electrode CNE1 may electrically connect the first source S1 and the conductive pattern CP. The one first connecting electrode CNE1 may be connected to the conductive pattern CP through a contact hole CH2 that penetrates the third insulating layer 30 and the fifth insulating layer 50.

The second connecting electrode CNE2 connected to at least one of the second source S2 and the second drain D2 may be disposed on the fifth insulating layer 50. In the example illustrated in FIG. 6, two second connecting electrodes CNE2 are connected to the second source S2 and the second drain D2, respectively, but embodiments are not limited thereto. The second connecting electrodes CNE2 are connected to corresponding areas of the second source S2 and the second drain D2 through contact holes CH1 penetrating the fifth insulating layer 50.

The third connecting electrode CNE3 connected to at least one of the fifth source S5 and the fifth drain D5 may be disposed on the fifth insulating layer 50. In the example illustrated in FIG. 6, two third connecting electrodes CNE3 are connected to the fifth source S5 and the fifth drain D5, respectively, but embodiments are not limited thereto. The third connecting electrodes CNE3 are connected to corresponding areas of the fifth source S5 and the fifth drain D5 through contact holes CH3 that penetrate the first insulating layer 10, the second insulating layer 20, the third insulating layer 30, the fifth insulating layer 50. Unlike the example shown in FIG. 6, one connecting electrode may connect the first drain D1 and the fifth drain D5.

A sixth insulating layer 60 is disposed on the fifth insulating layer 50. The sixth insulating layer 60 may cover the connecting electrodes CNE1, CNE2, and CNE3. In embodiments, the sixth insulating layer 60 may be an organic layer and may have a single-layer structure. However, embodiments are not limited thereto.

A conductive layer (which may be referred to as the fifth conductive layer) is disposed on the sixth insulating layer 60. The fifth conductive layer may include a plurality of conductive patterns. The fifth conductive layer includes a fourth connecting electrode CNE4. The fourth connecting electrode CNE4 is connected to the first connecting electrode CNE1 through a contact hole CH4 that penetrates the sixth insulating layer 60.

The fifth conductive layer may further include the data line DLj and the first voltage line VL1. The data line DLj may be connected to the second connecting electrode CNE2 through a contact hole CH4 that penetrates the sixth insulating layer 60. A portion of the first voltage line VL1 that overlaps the first electrode AE of the light emitting element OLED described below defines the third-second capacitor pattern E3-2 of the third capacitor C3 illustrated in FIG. 6. A portion of the first electrode AE of the light emitting element OLED defines the third-first capacitor pattern E3-1 of the third capacitor C3 illustrated in FIG. 6.

A seventh insulating layer 70 is disposed on the sixth insulating layer 60 to cover the fifth conductive layer. In embodiments, the seventh insulating layer 70 may be an organic layer and may have a single-layer structure. However, embodiments are not limited thereto.

The first electrode AE of the light emitting element OLED is disposed on the seventh insulating layer 70. The first electrode AE may be an anode. The first electrode AE is connected to the fourth connecting electrode CNE4 through a contact hole CH5 that penetrates the seventh insulating layer 70. A pixel defining layer PDL is disposed on the seventh insulating layer 70.

An opening OP of the pixel defining layer PDL exposes at least a portion of the first electrode AE. The opening OP of the pixel defining layer PDL may define an emissive area LA. For example, the plurality of pixels PX (e.g., as shown in FIG. 2) may be disposed on a plane of the display panel DP according to a predetermined rule or pattern. The area in which the plurality of pixels PX are disposed may be referred to as a display area, and the display area may include a plurality of emissive areas LA and a non-emissive area adjacent to the emissive areas LA. The non-emissive area NLA may be around or surround the emissive area LA.

A hole control layer HCL may be commonly disposed in the emissive area LA and the non-emissive area NLA. A common layer, such as the hole control layer HCL, may be commonly formed in the plurality of pixels PX. The hole control layer HCL may include a hole transport layer and a hole injection layer.

The emissive layer EML is disposed on the hole control layer HCL. The emissive layer EML may be disposed only in the area corresponding to the opening OP. The emissive layer EML may be separately formed in each of the plurality of pixels PX.

Although the patterned emissive layer EML is illustrated as an example in embodiments, the emissive layer EML may be commonly disposed in the plurality of pixels PX. The commonly disposed emissive layer EML may generate white light or blue light. In addition, the emissive layer EML may have a multi-layer structure.

An electron control layer ECL is disposed on the emissive layer EML. The electron control layer ECL may include an electron transport layer and an electron injection layer. The second electrode CE is disposed on the electron control layer ECL. The electron control layer ECL and the second electrode CE are commonly disposed in the plurality of pixels PX.

The thin film encapsulation layer TFE is disposed on the second electrode CE. The thin film encapsulation layer TFE is commonly disposed in the plurality of pixels PX. In embodiments, the thin film encapsulation layer TFE directly covers the second electrode CE. In an embodiment of the present disclosure, a capping layer that directly covers the second electrode CE may be further disposed. In an embodiment of the present disclosure, the stack structure of the light emitting element OLED may have a structure obtained by inverting the structure illustrated in FIG. 6.

The thin film encapsulation layer TEF includes at least an inorganic layer or an organic layer. In an embodiment of the present disclosure, the thin film encapsulation layer TFE may include two inorganic layers and an organic layer disposed therebetween. In an embodiment of the present disclosure, the thin film encapsulation layer TFE may include a plurality of inorganic layers and a plurality of organic layers alternately stacked one above another.

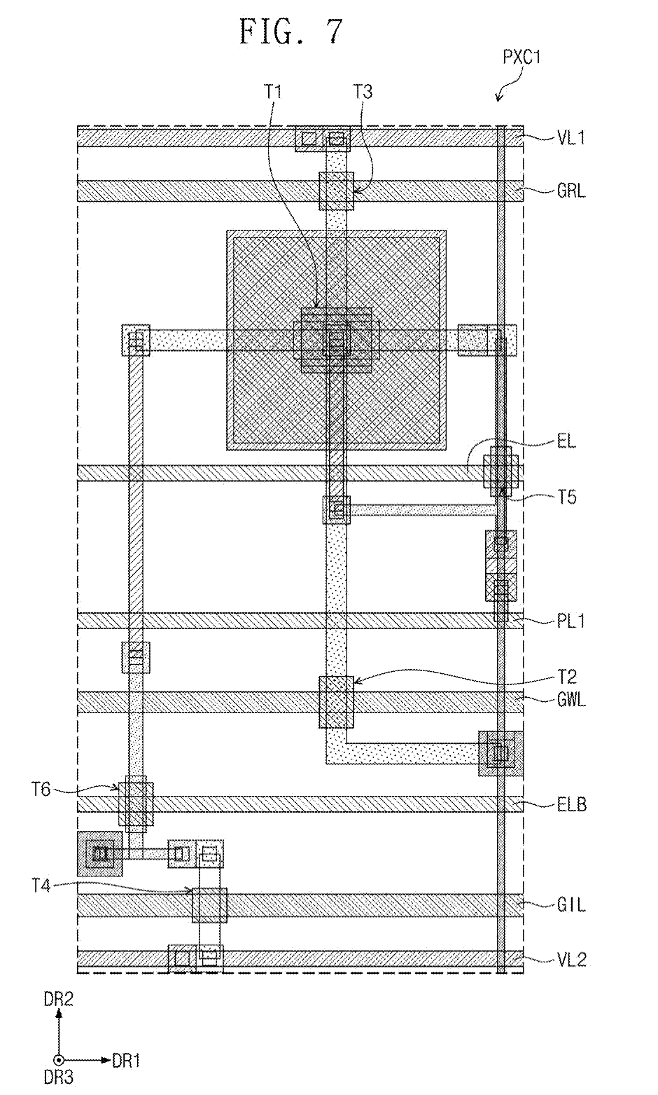

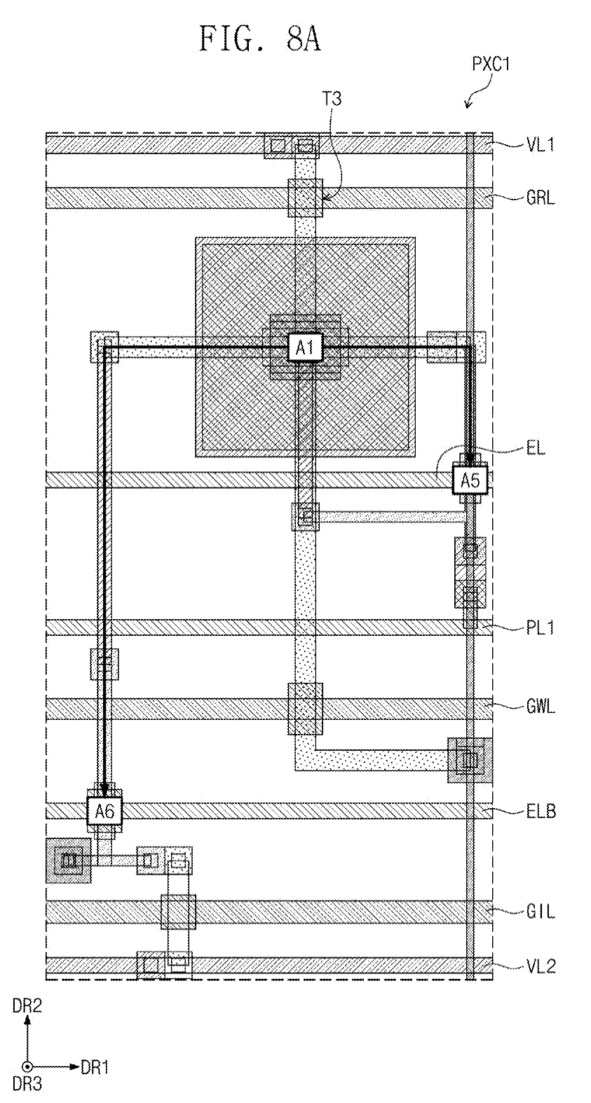

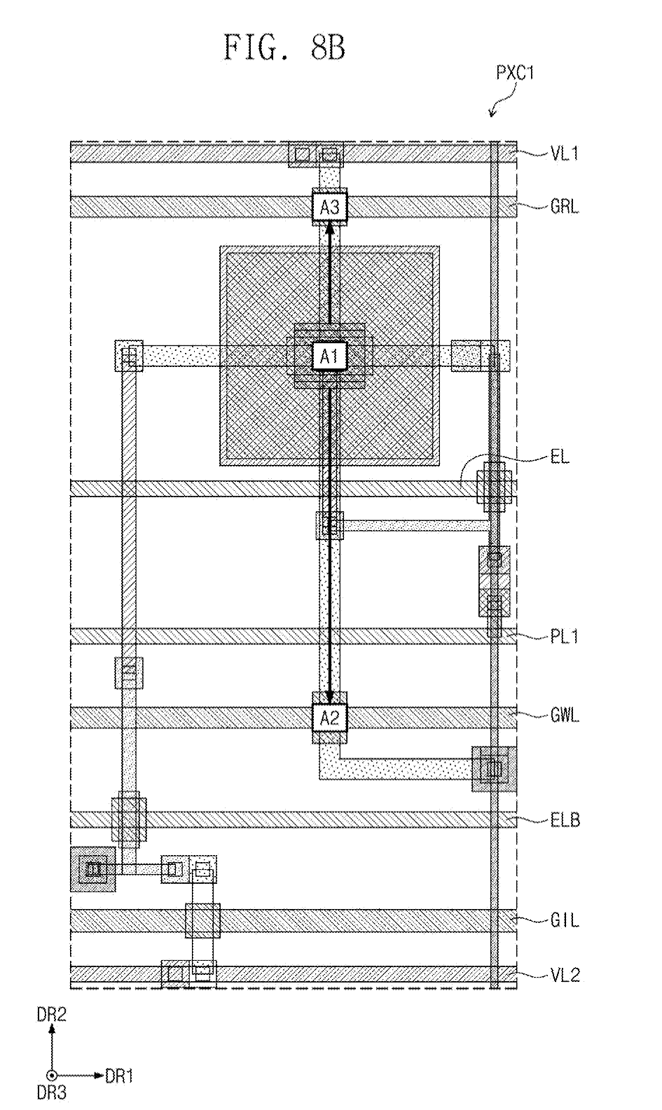

FIG. 7 is a schematic view illustrating a pixel circuit according to an embodiment of the present disclosure. FIGS. 8A and 8B are schematic views illustrating the pixel circuit illustrated in FIG. 7. FIGS. 7, 8A, and 8B illustrate an example of an arrangement relationship between the transistors and the signal lines illustrated in the circuit diagram of FIG. 5. Signal lines described with reference to FIGS. 7, 8A, and 8B may correspond to the signal lines described with reference to FIG. 5, and some components are omitted.

Referring to FIG. 7, the pixel circuit PXC1 according to an embodiment may include a first voltage line VL1, a reference scan line GRL disposed below the first voltage line VL1, a first emission signal line EL disposed below the reference scan line GRL, a first power line PL1 disposed below the first emission signal line EL, a write scan line GWL disposed below the first power line PL1, a second emission signal line ELB disposed below the write scan line GWL, an initialization scan line GIL disposed below the second emission signal line ELB, and a second voltage line VL2 disposed below the initialization scan line GIL.

For example, the pixel circuit PXC1 may include the first voltage line VL1, the reference scan line GRL, the first emission signal line EL, the first power line PL1, the write scan line GWL, the second emission signal line ELB, the initialization scan line GIL, and the second voltage line VL2 sequentially arranged from a top of the pixel circuit PXC1 in the second direction DR2.

A third transistor T3 may overlap the reference scan line GRL and may be connected with the reference scan line GRL. A first transistor T1 may be disposed between the reference scan line GRL and the first emission signal line EL. A fifth transistor T5 may overlap the first emission signal line EL and may be connected with the first emission signal line EL. A second transistor T2 may overlap the write scan line GWL and may be connected with the write scan line GWL. A sixth transistor T6 may overlap the second emission signal line ELB and may be connected with the second emission signal line ELB. A fourth transistor T4 may overlap the initialization scan line GIL and may be connected with the initialization scan line GIL.

In FIG. 8A, a first semiconductor pattern A1 included in the first transistor T1, a fifth semiconductor pattern A5 included in the fifth transistor T5, and a sixth semiconductor pattern A6 included in the sixth transistor T6 are illustrated.

In FIG. 8B, the first semiconductor pattern A1 included in the first transistor T1, a second semiconductor pattern A2 included in the second transistor T2, and a third semiconductor pattern A3 included in the third transistor T3 are illustrated.

According to an embodiment, on the plane of the pixel circuit PXC1, the first semiconductor pattern A1 may be disposed above the fifth semiconductor pattern A5 and the sixth semiconductor pattern A6. The fifth semiconductor pattern A5 may be disposed between the first semiconductor pattern A1 and the sixth semiconductor pattern A6. The fifth semiconductor pattern A5 and the sixth semiconductor pattern A6 may include poly silicon.

The second semiconductor pattern A2 may be disposed below the first semiconductor pattern A1. The third semiconductor pattern A3 may be disposed above the first semiconductor pattern A1.

According to embodiments, coupling capacitance occurring between signal lines adjacent to the line included in the second node ND2 described with reference to FIG. 5, (e.g., the line that connects the gate G1 of the first transistor T1, the source S2 of the second transistor T2, the drain D3 of the third transistor T3, and the first-second capacitor pattern E1-2 of the first capacitor C1) may be minimized through the optimal design of the pixel circuit PXC1.

In addition, according to embodiments, by placing the first power line PL1, to which a constant voltage is applied, below the line included in the second node ND2, coupling capacitance occurring between signal lines adjacent to the line included in the second node ND2 may be minimized.

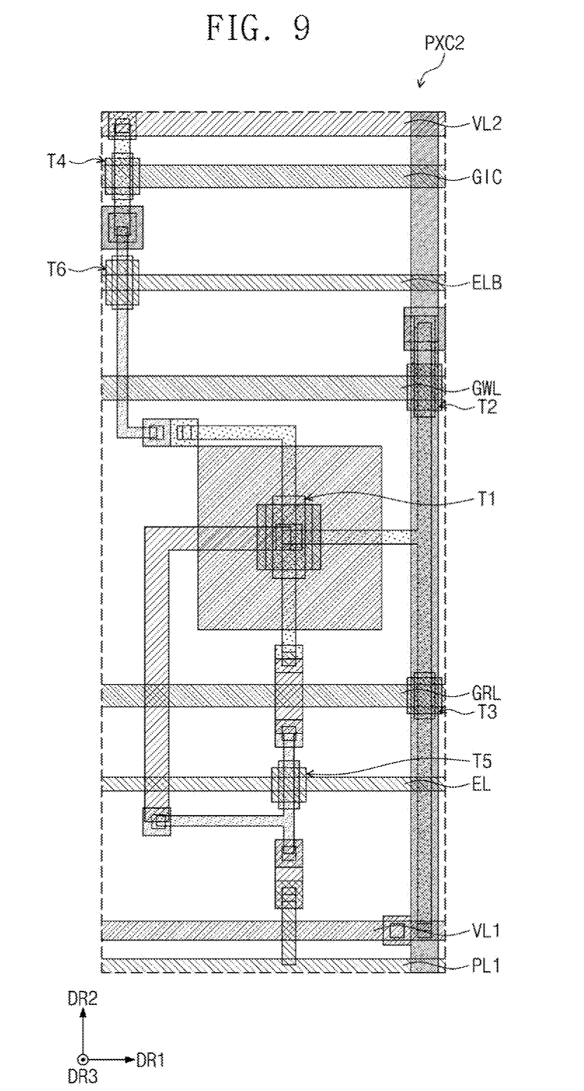

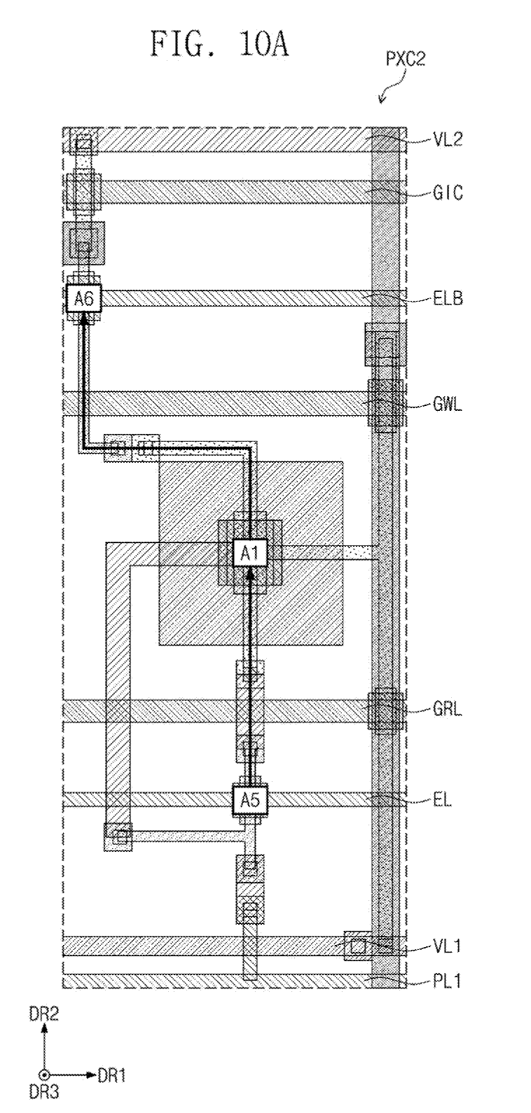

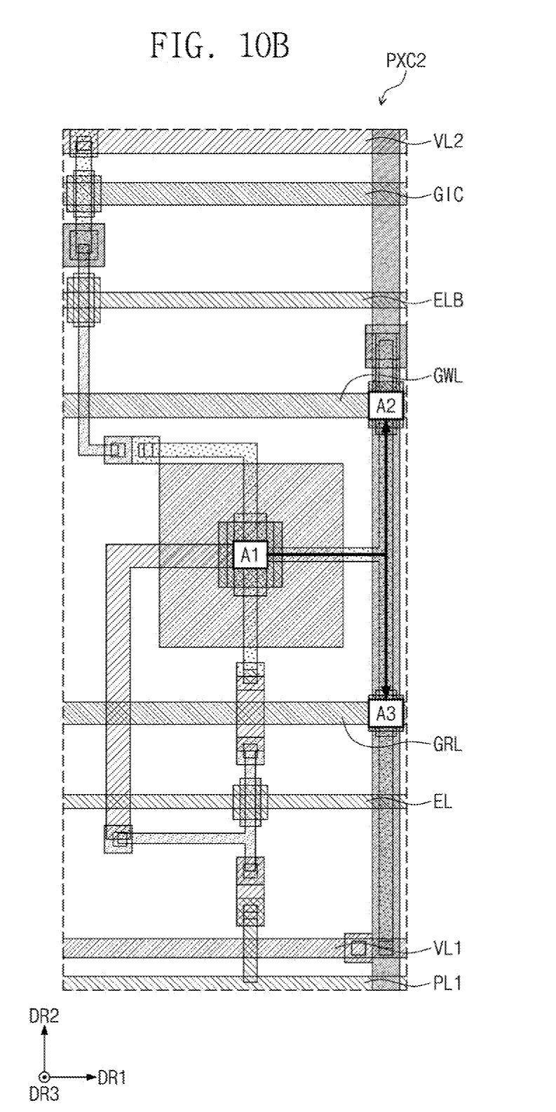

FIG. 9 is a schematic view illustrating a pixel circuit according to an embodiment of the present disclosure. FIGS. 10A and 10B are schematic views illustrating the pixel circuit illustrated in FIG. 9. FIGS. 9, 10A and 10B illustrate an example of an arrangement relationship between the transistors and the signal lines illustrated in the circuit diagram of FIG. 5. Signal lines described with reference to FIGS. 9, 10A and 10B may correspond to the signal lines described with reference to FIG. 5, and some components are omitted.

Referring to FIG. 9, the pixel circuit PXC2 according to an embodiment may include a second voltage line VL2, an initialization scan line GIL disposed below the second voltage line VL2, a second emission signal line ELB disposed below the initialization scan line GIL, a write scan line GWL disposed below the second emission signal line ELB, a reference scan line GRL disposed below the write scan line GWL, a first emission signal line EL disposed below the reference scan line GRL, a first voltage line VL1 disposed below the first emission signal line EL, and a first power line PL1 disposed below the first voltage line VL1.

That is, the pixel circuit PXC2 may include the second voltage line VL2, the initialization scan line GIL, the second emission signal line ELB, the write scan line GWL, the reference scan line GRL, the first emission signal line EL, the first voltage line VL1, and the first power line PL1 sequentially arranged from the top of the pixel circuit PXC2 in the second direction DR2.

A fourth transistor T4 may overlap the initialization scan line GIL and may be connected with the initialization scan line GIL. A sixth transistor T6 may overlap the second emission signal line ELB and may be connected with the second emission signal line ELB. A second transistor T2 may overlap the write scan line GWL and may be connected with the write scan line GWL. A first transistor T1 may be disposed between the write scan line GWL and the reference scan line GRL. A third transistor T3 may overlap the reference scan line GRL and may be connected with the reference scan line GRL. A fifth transistor T5 may overlap the first emission signal line EL and may be connected with the first emission signal line EL.

In FIG. 10A, an example is illustrated which includes a first semiconductor pattern A1 included in the first transistor T1, a fifth semiconductor pattern A5 included in the fifth transistor T5, and a sixth semiconductor pattern A6 included in the sixth transistor T6.

In FIG. 10B, an example is illustrated which includes the first semiconductor pattern A1 included in the first transistor T1, a second semiconductor pattern A2 included in the second transistor T2, and a third semiconductor pattern A3 included in the third transistor T3.

According to an embodiment, on the plane of the pixel circuit PXC2, the fifth semiconductor pattern A5 may be disposed below the first semiconductor pattern A1. The sixth semiconductor pattern A6 may be disposed above the first semiconductor pattern A1. The first semiconductor pattern A1 may be disposed between the fifth semiconductor pattern A5 and the sixth semiconductor pattern A6. The fifth semiconductor pattern A5 and the sixth semiconductor pattern A6 may include poly silicon.

The third semiconductor pattern A3 may be disposed below the first semiconductor pattern A1. The second semiconductor pattern A2 may be disposed above the first semiconductor pattern A1.

According to embodiments, coupling capacitance occurring between signal lines adjacent to the line included in the second node ND2 described with reference to FIG. 5 (e.g., the line that connects the gate G1 of the first transistor T1, the source S2 of the second transistor T2, the drain D3 of the third transistor T3, and the first-second capacitor pattern E1-2 of the first capacitor C1) may be minimized through the optimal design of the pixel circuit PXC2.

According to embodiments of the present disclosure, the coupling capacitance occurring between the signal lines adjacent to the line included in the node connecting the transistors may be minimized through the optimal design of the pixel circuit. Accordingly, the electronic device with improved reliability may be provided.

Although some particular embodiments of the present disclosure are described above, it will be apparent to those of ordinary skill in the art that various changes and modifications may be made thereto without departing from the spirit and scope of the present disclosure as set forth in the following claims.

What is claimed is:

1. An electronic device comprising:
a processor configured to provide image data and a display brightness value;
a display panel comprising a pixel circuit including a plurality of transistors and a plurality of capacitors, a light emitting element connected to the pixel circuit, and a signal line connected to the plurality of transistors; and
a panel driver configured to receive the image data and the display brightness value, and to drive the display panel based on the image data and the display brightness value,
wherein on a plane, the signal line comprises:
a first voltage line;
a reference scan line below the first voltage line;
a first emission signal line below the reference scan line;
a first power line below the first emission signal line;
a write scan line below the first power line;
a second emission signal line below the write scan line;
an initialization scan line below the second emission signal line; and
a second voltage line below the initialization scan line.

2. The electronic device of claim 1, wherein the plurality of transistors comprise a first transistor, a second transistor, a third transistor, a fourth transistor, a fifth transistor, and a sixth transistor, and
wherein the first transistor, the second transistor, the third transistor, and the fourth transistor correspond to a first transistor type, and
wherein the fifth transistor and the sixth transistor correspond to a second transistor type different from the first transistor type.

3. The electronic device of claim 2, further comprising:
a first node connected to the first transistor and the light emitting element,
wherein the first transistor is connected between the first node and the first power line,
wherein the fifth transistor is connected between the first power line and a drain of the first transistor, and is connected to the first emission signal line,
wherein the sixth transistor is connected between the first node and the light emitting element, and is connected to the second emission signal line,
wherein the fifth transistor is configured to receive a first emission signal using the first emission signal line, and
wherein the sixth transistor is configured to receive a second emission signal using the second emission signal line.

4. The electronic device of claim 3, wherein on the plane, a first semiconductor pattern corresponding to the first transistor is above a fifth semiconductor pattern corresponding to the fifth transistor and a sixth semiconductor pattern corresponding to the sixth transistor.

5. The electronic device of claim 4, wherein on the plane, the fifth semiconductor pattern is between the first semiconductor pattern and the sixth semiconductor pattern.

6. The electronic device of claim 4, wherein the fifth semiconductor pattern and the sixth semiconductor pattern comprise poly silicon.

7. The electronic device of claim 2, further comprising:
a second node connected to the first transistor and the second transistor,
wherein the second transistor is connected between the second node and the write scan line, and is connected to a data line,
wherein the third transistor is connected between the second node and the first voltage line, and is connected to the reference scan line,
wherein the first voltage line is configured to receive a reference voltage,
wherein the second transistor is configured to receive a data signal using the data line, and
wherein the third transistor is configured to receive a reference scan signal using the reference scan line.

8. The electronic device of claim 7, wherein on the plane, a second semiconductor pattern corresponding to the second transistor is below a first semiconductor pattern corresponding to the first transistor, and
wherein a third semiconductor pattern corresponding to the third transistor is above the first semiconductor pattern.

9. The electronic device of claim 8, wherein the first semiconductor pattern, the second semiconductor pattern, and the third semiconductor pattern comprise an oxide semiconductor.

10. The electronic device of claim 2, wherein on the plane, a first semiconductor pattern corresponding to the first transistor is between the reference scan line and the first emission signal line.

11. An electronic device comprising:
a processor configured to provide image data and a display brightness value;
a display panel comprising a pixel circuit, wherein the pixel circuit comprises a plurality of transistors, a plurality of capacitors, a light emitting element connected to the pixel circuit, and a signal line connected to the plurality of transistors; and
a panel driver configured to receive the image data and the display brightness value, and to drive the display panel based on the image data and the display brightness value,
wherein on a plane, the signal line comprises:
a second voltage line;
an initialization scan line below the second voltage line;
a second emission signal line below the initialization scan line;
a write scan line below the second emission signal line;
a reference scan line below the write scan line;
a first emission signal line below the reference scan line;
a first voltage line below the first emission signal line; and
a first power line below the first voltage line.

12. The electronic device of claim 11, wherein the plurality of transistors comprise a first transistor, a second transistor, a third transistor, a fourth transistor, a fifth transistor, and a sixth transistor, and
wherein the first transistor, the second transistor, the third transistor, and the fourth transistor correspond to a first transistor type, and
wherein the fifth transistor and the sixth transistor correspond to a second transistor type different from the first transistor type.

13. The electronic device of claim 12, further comprising:
a first node connected to the first transistor and the light emitting element,
wherein the first transistor is connected between the first node and the first power line,
wherein the fifth transistor is connected between the first power line and a drain of the first transistor, and connected is connected to the first emission signal line,
wherein the sixth transistor is connected between the first node and the light emitting element and connected to the second emission signal line,
wherein the fifth transistor is configured to receive a first emission signal using the first emission signal line, and
wherein the sixth transistor is configured to receive a second emission signal using the second emission signal line.

14. The electronic device of claim 13, wherein on the plane, a fifth semiconductor pattern corresponding to the fifth transistor is below a first semiconductor pattern corresponding to the first transistor, and
wherein a sixth semiconductor pattern corresponding to the sixth transistor is above the first semiconductor pattern corresponding to the first transistor.

15. The electronic device of claim 14, wherein the fifth semiconductor pattern and the sixth semiconductor pattern comprise poly silicon.

16. The electronic device of claim 12, further comprising:
a second node connected to the first transistor and the second transistor,
wherein the second transistor is connected between the second node and the write scan line, and is connected to a data line,
wherein the third transistor is connected between the second node and the first voltage line, and is connected to the reference scan line,
wherein the first voltage line is configured to receive a reference voltage,
wherein the second transistor is configured to receive a data signal using the data line, and
wherein the third transistor is configured to receive a reference scan signal using the reference scan line.

17. The electronic device of claim 16, wherein on the plane, a second semiconductor pattern corresponding to the second transistor is above a first semiconductor pattern corresponding to the first transistor, and
wherein a third semiconductor pattern of the third transistor is below the first semiconductor pattern corresponding to the first transistor.

18. The electronic device of claim 17, wherein the first semiconductor pattern, the second semiconductor pattern, and the third semiconductor pattern comprise an oxide semiconductor.

19. The electronic device of claim 12, wherein on the plane, a first semiconductor pattern corresponding to the first transistor is between the write scan line and the reference scan line.

20. The electronic device of claim 11, wherein the light emitting element comprises a first electrode, a second electrode, and an emissive layer between the first electrode and the second electrode.
